(19) United States
(12) Patent Application Publication
(10) Pub. No.: US 2025/0192104 A1
(43) Pub. Date: Jun. 12, 2025

(54) SEMICONDUCTOR STRUCTURE HAVING ALIGNMENT PATTERN AND MANUFACTURING METHOD THEREOF

(71) Applicant: Taiwan Semiconductor Manufacturing Company, Ltd., Hsinchu (TW)

(72) Inventors: Ting-Hung Hsu, MiaoLi (TW); Chen Hua Huang, Taoyuan County (TW); Tsai-Hao Hung, Hsinchu (TW); Cheng-Hsien Hsieh, Kaohsiung City (TW); Li-Han Hsu, Hsin-Chu City (TW)

(73) Assignee: Taiwan Semiconductor Manufacturing Company, Ltd., Hsinchu (TW)

(21) Appl. No.: 18/533,077

(22) Filed: Dec. 7, 2023

(51) Int. Cl. H01L 25/065; H01L 23/00; H01L 23/544; H01L 25/00

(52) U.S. Cl. CPC H01L 25/0657; H01L 23/544; H01L 24/08; H01L 24/80; H01L 25/50; H01L 2223/54426; H01L 2224/0217; H01L 2224/08146; H01L 2224/8013; H01L 2224/80895; H01L 2224/80896; H01L 2225/06541; H01L 2225/06586; H01L 2225/06593

(57) ABSTRACT

A semiconductor structure includes a first and second integrated circuit (IC) components stacked upon and electrically coupled to each other. The first IC component includes a first bonding structure including a first bonding dielectric layer and a first bonding feature disposed in the first bonding dielectric layer, and a first alignment pattern disposed in the first bonding dielectric layer. The second IC component includes a second bonding structure including a second bonding dielectric layer bonded to the first bonding dielectric layer and a second bonding feature disposed in the second bonding dielectric layer and bonded to the first bonding feature, and a second alignment pattern disposed in the second bonding dielectric layer and aligned with the first alignment pattern in a staggered manner. The second alignment pattern is disposed within a boundary of the first IC component in a top-down view.

### BACKGROUND

The semiconductor industry has experienced rapid growth due to continuous improvement in integration density of various components, e.g., transistors, diodes, resistors, capacitors, etc. For the most part, this improvement in integration density has come from successive reductions in minimum feature size, which allows more components to be integrated into a given area. Technological advances in integrated circuit (IC) design have produced generations of ICs where each generation has smaller and more complex circuit designs than the previous generation. There is continuous effort in developing new mechanisms of forming semiconductor structures having improved electrical performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic cross-sectional view of a first integrated circuit (IC) component according to some embodiments.

FIG. 1B illustrates a schematic top-down plan view of the first IC component shown in FIG. 1A according to some embodiments.

FIG. 2A illustrates a schematic cross-sectional view of a second IC component according to some embodiments.

FIG. 2B illustrates a schematic top-down plan view of the second IC component shown in FIG. 2A according to some embodiments.

FIGS. 3A, 3D, and 3E illustrate schematic cross-sectional views of intermediate steps during a process for forming a semiconductor structure, in accordance with some embodiments.

FIG. 3B illustrates a schematic top-down plan view of the bonded structure shown in FIG. 3A according to some embodiments.

FIG. 3C illustrates a schematic and partial perspective view of the bonded structure shown in FIG. 3A according to some embodiments.

FIG. 4A illustrates a schematic cross-sectional view of a first IC component according to some embodiments.

FIG. 4B illustrates a schematic top-down plan view of the first IC component shown in FIG. 4A according to some embodiments.

FIGS. 5A and 5B illustrate schematic cross-sectional views of intermediate steps during a process for forming a semiconductor structure, in accordance with some embodiments.

FIGS. 6A and 6B illustrate schematic cross-sectional views of different semiconductor structures, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein are to provide various semiconductor structures including integrated circuit (IC) components with alignment marks and methods for forming a semiconductor structure having such IC components. By forming IC components having alignment marks, undesired shift or misalignment of IC components may be reduced or avoided while bonding an IC component to another IC component. Moreover, damage to IC components caused by misalignment may be reduced or avoided. In some embodiments, a semiconductor structure including the upper IC component bonded to the lower IC component is described herein. The semiconductor structure may be or includes a system on integrated chip (SoIC) or the like.

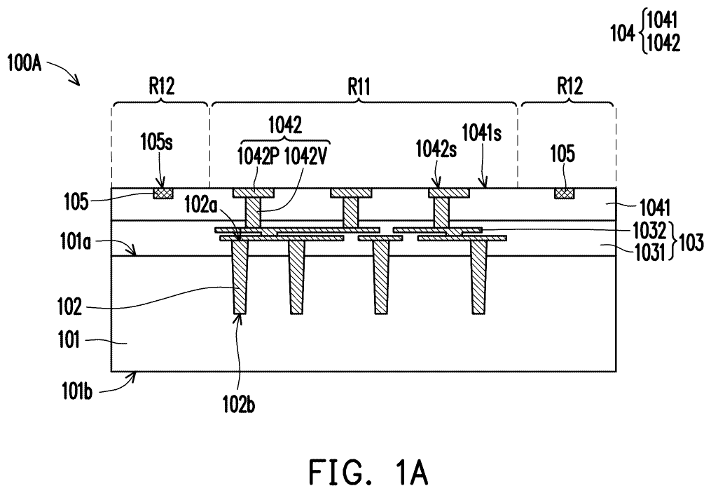

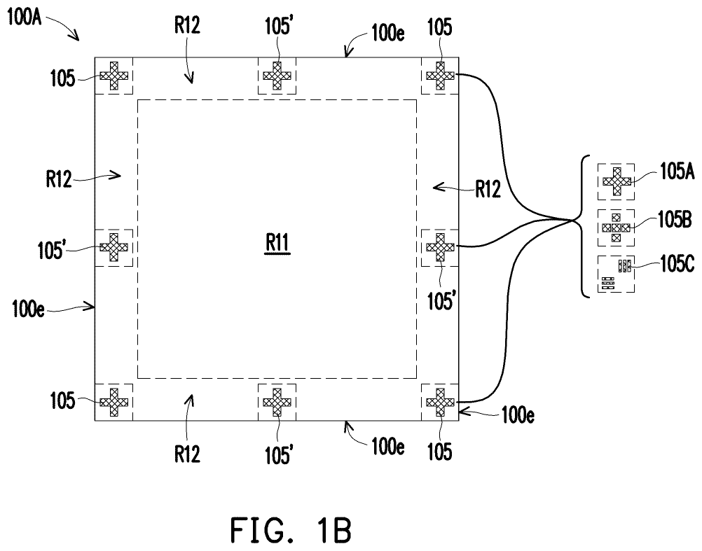

FIG. 1A illustrates a schematic cross-sectional view of a first integrated circuit (IC) component, and FIG. 1B illustrates a schematic top-down plan view of the first IC component shown in FIG. 1A, in accordance with some embodiments. It should be noted that FIGS. 1A and 1B are provided for illustrative purposes only, and the first IC component may utilize fewer or additional elements according to alternative embodiments.

Referring to FIG. 1A, a first IC component 100A is provided. In some embodiments, the first IC component 100A is implemented as a semiconductor die (or chip) which may be formed in a device wafer (not shown), and the device wafer may include more than one functional regions (or die regions) that are singulated in subsequent steps to form a plurality of semiconductor dies. For example, the first IC component 100A includes a first semiconductor substrate 101, such as silicon, doped or undoped, or an active layer of a semiconductor-on-insulator (SOI) substrate. The first semiconductor substrate 101 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrate (e.g., a multi-layered substrate or a gradient substrate) may be used. The first semiconductor substrate 101 may include a front side 101a and a back side 101b opposite to the front side 101a. Devices (not individually shown; e.g., transistors, diodes, capacitors, resistors, or the like) may (or may not) be formed at the front side 101a of the first semiconductor substrate 101.

In some embodiments, the first IC component 100A includes a first interconnect structure 103 disposed over the first semiconductor substrate 101. The first interconnect structure 103 may be formed of alternating layers of dielectric (e.g., low-k dielectric material) and conductive material (e.g., copper) with vias interconnecting the layers of conductive material and may be formed through any suitable process (such as deposition, single damascene, dual damascene, or the like). For example, the first interconnect structure 103 includes one or more first dielectric layer(s) 1031 and first metallization patterns 1032 disposed in the first dielectric layer 1031. The first metallization patterns 1032 may include conductive lines, conductive pads, and conductive vias, and may be electrically coupled to the devices to form an integrated circuit. In some embodiments, the first IC component 100A includes through substrate vias (TSVs) 102 formed in the first semiconductor substrate 101 by depositing one or more diffusion barrier layer(s) or isolation layer(s), depositing a seed layer, and depositing a conductive material (e.g., tungsten, titanium, aluminum, copper, any combinations thereof and/or the like) into the trenches of the first semiconductor substrate 101. For example, the respective TSV 102 includes a first end 102a physically and electrically connected to one of the first metallization patterns 1032 and a second end 102b opposite to the first end 102a, where the second end 102b may be buried in the first semiconductor substrate 101 at this stage.

With continued reference to FIG. 1A, the first IC component 100A may include a first bonding structure 104 disposed over the first interconnect structure 103. The first bonding structure 104 may include one or more first bonding dielectric layer(s) 1041 and first bonding features 1042 laterally covered by the first bonding dielectric layer 1041. The first bonding dielectric layer 1041 subsequently used for bonding includes one or more dielectric material(s) (e.g., silicon nitride, silicon oxide, and/or the like). In some embodiments, the first bonding dielectric layer 1041 and the first dielectric layer 1031 underlying the first bonding dielectric layer 1041 include different dielectric materials. The first bonding dielectric layer 1041 may be formed using chemical vapor deposition (CVD), physical vapor deposition (PVD), atomic layer deposition (ALD), a spin-on coating process, a combination thereof, or the like. The respective first bonding feature 1042 may be or include a bonding pad 1042P and/or a bonding via 1042V, and may be formed using a damascene process (e.g., a single damascene process or a dual damascene process). The first bonding features 1042 may include one or more conductive material(s), which may be a metallic material including a metal or a metal alloy such as copper, silver, gold, tungsten, cobalt, aluminum, or alloys thereof.

In the illustrated embodiment, the bonding via 1042V lands on the topmost one the first metallization patterns 1032, and the bonding pad 1042P overlies the bonding via 1042V. In alternative embodiments, the bonding pads 1042P are omitted, and the respective bonding via 1042V passing through the first bonding dielectric layer 1041 has one end landing on any one of the first metallization patterns 1032 and an opposing end substantially leveled with (and/or exposed by) the first bonding dielectric layer 1041. The first bonding structure 104 may have other configuration according to some other embodiments. In some embodiments, a planarization process (e.g., chemical mechanical polishing (CMP), grinding, etching, a combination thereof, etc.) is performed on the first bonding structure 104 such that bonding surfaces 1042s of the first bonding features 1042 and a bonding surface 1041s of the first bonding dielectric layer 1041 are substantially leveled (or coplanar), within process variations.

Still referring to FIG. 1A, the first IC component 100A may include one or more first alignment pattern(s) 105 formed in the first bonding structure 104. For example, the first alignment patterns 105 are laterally covered by the first bonding dielectric layer 1041. The first alignment patterns 105 may be made of conductive material. For example, the first alignment patterns 105 are formed simultaneously with forming the first bonding features 1042 (e.g., the bonding pads 1042P). In other embodiments, the first bonding features 1042 and the first alignment patterns 105 are formed at different steps and include different conductive materials. In some embodiments, the first alignment patterns 105 are dummy structures which are electrically decoupled or electrically isolated from any of the conductive features in the first IC component 100A. The first alignment patterns 105 may be electrically floating in the first IC component 100A. In some embodiments, the first alignment patterns 105 are made of a non-conductive material, such as an insulating material or the like. The non-conductive material of the first alignment patterns 105 may be different than the first bonding dielectric layer 1041 such that a visible difference is distinguished between the first alignment patterns 105 and the first bonding dielectric layer 1041. In some embodiments, during the planarization process performed on the first bonding structure 104, surfaces 105s of the first alignment patterns 105 may be planarized to be substantially leveled (or coplanar) with the bonding surfaces 1042s of the first bonding features 1042 and the bonding surface 1041s of the first bonding dielectric layer 1041, within process variations.

Referring to FIG. 1B and with reference to FIG. 1A, the first IC component 100A may include a first region R11 and a second region R12 surrounding the first region R11. For example, the first region R11 is a functional region (or an active region) in which the first bonding features 1042 are disposed, and the second region R12 is a non-functional region (e.g., an inactive region or a peripheral region) in which the first alignment patterns 105 are disposed. In some embodiments, the seal ring structure (not shown) disposed at the intersection of the first and second regions R11 and R12 to separate the functional features in the first region R11 from the non-functional features in the second region R12. In some embodiments, the first alignment patterns 105 are distributed at the die corners as shown in the top-down plan view of FIG. 1B. Although it is illustrated that four alignment patterns are included in the first IC component 100A, the first alignment patterns 105 may each be identical to each other, set in pairs, or set in any other arrangement of similar or dissimilar patterns. Fewer or more alignment patterns may be included as well. The first alignment patterns 105 need not be placed in the die corners, but can be anywhere within the second region R12 of the first IC component 100A. In some embodiments, the first alignment patterns 105′ are located at (or near) midpoints of two opposing die edges 100e in the top-down plan view, where the first alignment patterns 105′ at the two opposing die edges 100e may be disposed in a symmetrical manner. In alternative embodiments, multiple first alignment patterns 105 are arranged alongside the die edges 100e, and may (or may not) be disposed in a symmetrical manner.

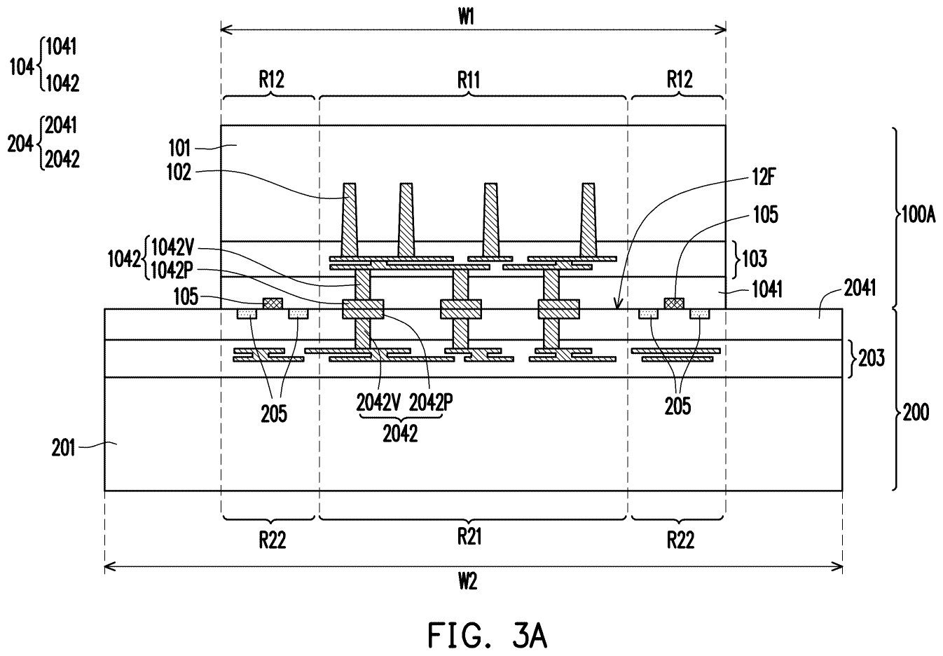

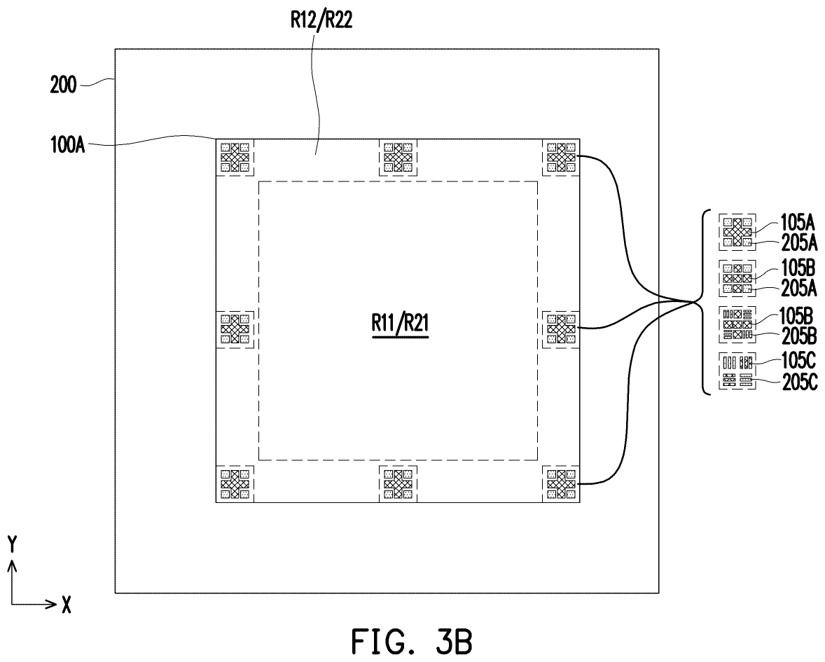

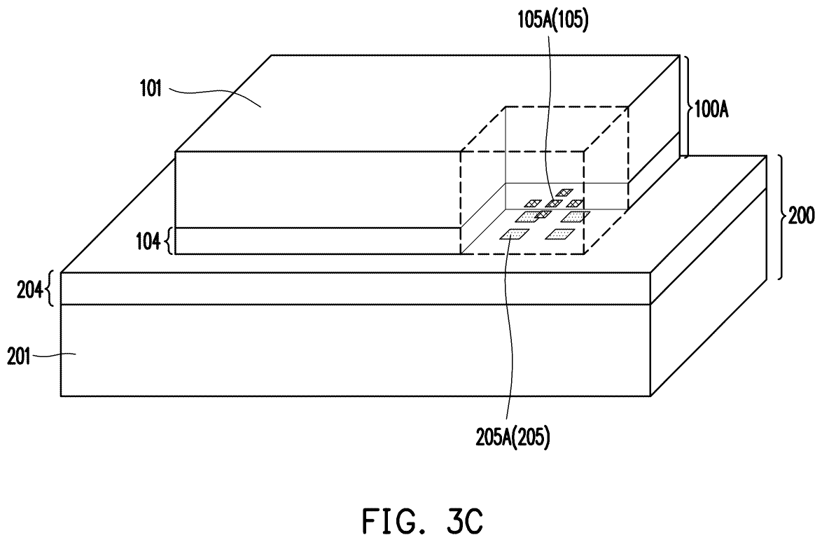

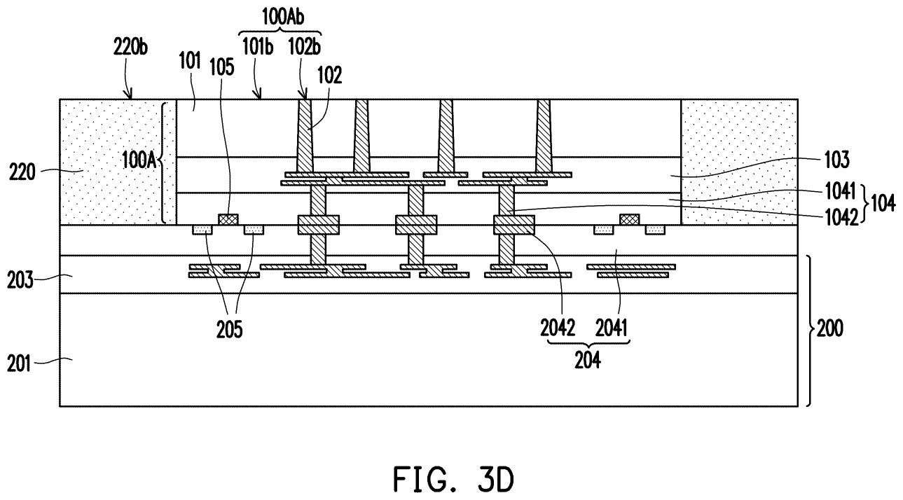

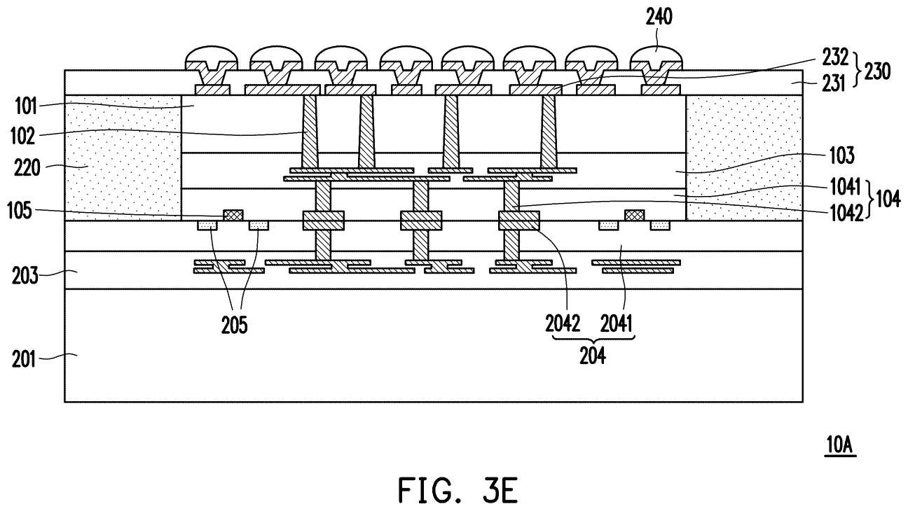

With continued reference to FIG. 1B, possible first alignment pattern designs are illustrated, in accordance with some embodiments. For example, the top view of the first alignment pattern 105A is in a continuous cross shape and located in the center of the dashed box framing the alignment pattern. In some embodiments, the top view of the first alignment pattern 105B includes discrete square (or rectangular) segments arranged to form a cross in the dashed box framing the alignment pattern. In some embodiments, the top view of the first alignment pattern 105C includes discrete vertical strips and discrete horizontal strips, where the discrete vertical strips are located at the upper and left portion of the dashed box framing the alignment pattern, and the discrete horizontal strips are located at the lower and right portion of the dashed box. The shape of the first alignment patterns 105A, 105B, and 105C are provided for illustrative purposes only and are not meant to limit the scope of the embodiments described herein. Any shape (e.g., circles, ovals, triangles, squares, L-shapes, a combination thereof, or the like) can be used as the first alignment patterns 105. The top-view shape of the first alignment pattern 105 at each die corner (or each die edge) may be the same or similar. In other embodiments, the top-view shapes of the first alignment patterns 105 at different locations may be different. The first alignment patterns 105 may be used to precisely align the first IC component 100A with a second IC component (see FIG. 3A; labeled in “200”).

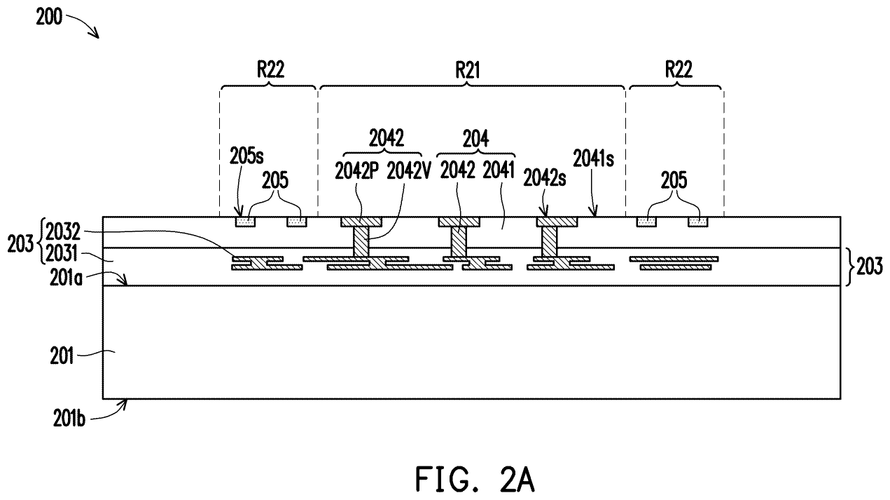

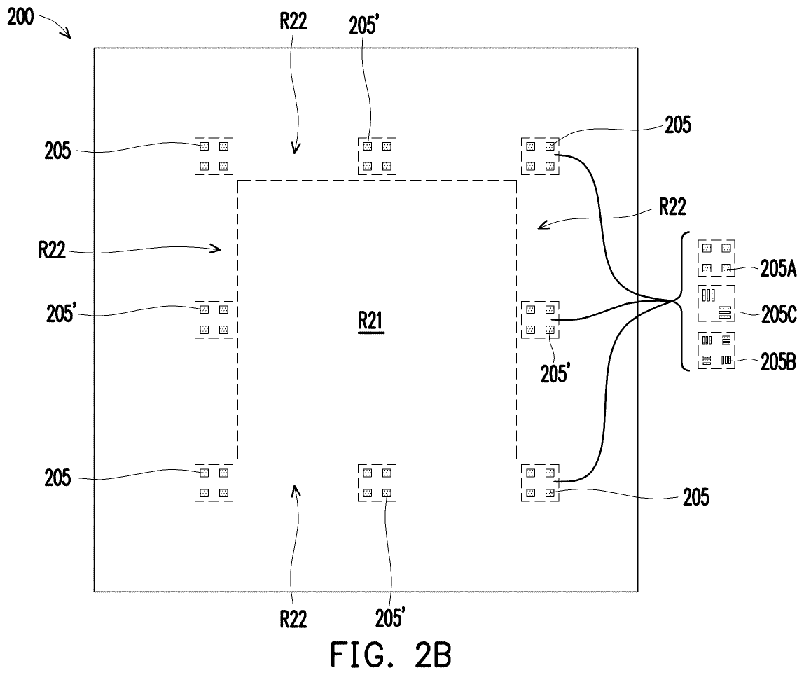

FIG. 2A illustrates a schematic cross-sectional view of a second IC component, and FIG. 2B illustrates a schematic top-down plan view of the second IC component shown in FIG. 2A, in accordance with some embodiments. It should be noted that FIGS. 2A and 2B are provided for illustrative purposes only, and the second IC component may utilize fewer or additional elements according to alternative embodiments.

Referring to FIG. 2A and with reference to FIG. 1A, a second IC component 200 is provided. In some embodiments, the second IC component 200 is implemented as a semiconductor wafer which may include one or more functional regions. For example, the second IC component 200 includes a second semiconductor substrate 201. The material of the second semiconductor substrate 201 may be similar to that of the first semiconductor substrate 101 described in FIG. 1A. The second semiconductor substrate 201 may include a front side 201a and a back side 201b opposite to the front side 201a. Devices (not individually shown; e.g., transistors, diodes, capacitors, resistors, or the like) may (or may not) be formed at the front side 201a of the second semiconductor substrate 201.

In some embodiments, the second IC component 200 includes a second interconnect structure 203 disposed over the second semiconductor substrate 201. For example, the second interconnect structure 203 includes one or more second dielectric layer(s) 2031 and second metallization patterns 2032 disposed in the second dielectric layer 2031. The second metallization patterns 2032 may include conductive lines, conductive pads, and conductive vias, and may be electrically coupled to the devices to form an integrated circuit. The second dielectric layer 2031 and the second metallization patterns 2032 of the second interconnect structure 203 may be similar to the first dielectric layer 1031 and the first metallization patterns 1032 of the first interconnect structure 103, respectively.

With continued reference to FIG. 2A and FIG. 1A, the second IC component 200 may include a second bonding structure 204 disposed over the second interconnect structure 203. The second bonding structure 204 may include one or more second bonding dielectric layer(s) 2041 overlying the second dielectric layer 2031 and second bonding features 2042 laterally covered by the second bonding dielectric layer 2041. The second bonding dielectric layer 2041 and the second bonding features 2042 may be similar to the first bonding dielectric layer 1041 and the first bonding features 1042, respectively. The respective second bonding feature 2042 may be or include a bonding pad 2042P and/or a bonding via 2042V. The bonding via 2042V may land on the one of the second metallization patterns 2032, and the bonding pad 2042P overlies the bonding via 2042V. In alternative embodiments, the bonding pads 2042P are omitted, and the respective bonding via 2042V passing through the second bonding dielectric layer 2041 has one end landing on one of the second metallization patterns 2032 and an opposing end exposed by the second bonding dielectric layer 2041. In some embodiments, bonding surfaces 2042s of the second bonding features 2042 and a bonding surface 2041s of the second bonding dielectric layer 2041 are substantially leveled (or coplanar), within process variations.

Still referring to FIG. 2A and FIG. 1A, the second IC component 200A may include one or more second alignment pattern(s) 205 formed in the second bonding structure 204 and laterally covered by the second bonding dielectric layer 2041. The material of the second alignment pattern 205 may be similar to that of the first alignment patterns 105 described in FIG. 1A. In some embodiments, the second alignment patterns 205 include one or more conductive material(s) and may be formed simultaneously with forming the second bonding features 2042 (e.g., the bonding pads 2042P). Alternatively, the second bonding features 2042 and the second alignment patterns 205 may be formed at different steps and/or may include different conductive materials. In some embodiments, the second alignment patterns 205 are dummy structures which are electrically decoupled or electrically isolated from any of the conductive features in the second IC component 200. The second alignment patterns 205 may be electrically floating in the second IC component 200. In some embodiments, the second alignment patterns 205 are made of a non-conductive material (e.g., an insulating material or any suitable material), and a visible interface is between the second alignment patterns 205 and the second bonding dielectric layer 2041. In some embodiments, during the planarization process performed on the second bonding structure 204, surfaces 205s of the second alignment patterns 205 may be planarized to be substantially leveled (or coplanar) with the bonding surfaces 2042s of the second bonding features 2042 and the bonding surface 2041s of the second bonding dielectric layer 2041, within process variations.

Referring to FIG. 2B and with reference to FIG. 2A and FIG. 1B, the second IC component 200 may include a first region R21 and a second region R22 surrounding the first region R21. For example, the first region R21 is a functional region (or an active region) in which the second bonding features 2042 are disposed, and the second region R22 is a non-functional region (e.g., an inactive region or a peripheral region). In some embodiments, the seal ring structure (not shown) disposed at the intersection of the first and second regions R21 and R22 to separate the functional features in the first region R21 from the non-functional features in the second region R22. The second alignment patterns 205 may be disposed in the second region R22 which does not affect the first region R21. In some embodiments, the second alignment patterns 205 are distributed at the location in proximity to (or corresponding to) the corner of the first region R21 as shown in the top-down plan view of FIG. 2B. In some embodiments, the second alignment patterns 205′ are located at (or near) midpoints of two opposing sides of the first region R21 in the top-down plan view, where the second alignment patterns 205′ at the two opposing sides of the first region R21 may be disposed in a symmetrical manner. In alternative embodiments, the second alignment patterns 205 are disposed alongside two opposing sides of the first region R21, and may (or may not) be disposed in a symmetrical manner.

With continued reference to FIG. 2B, possible second alignment pattern designs are illustrated, in accordance with some embodiments. For example, the top view of the second alignment patterns 205A includes discrete square (or rectangular) segments arranged at the corners of the dashed box framing the alignment pattern. In some embodiments, the top view of the second alignment patterns 205B includes discrete vertical strips and discrete horizontal strips, where the discrete vertical strips are located at the upper-left and lower-right portions of the dashed box framing the alignment pattern, and the discrete horizontal strips are located at the upper-right and lower-left portions of the dashed box. In some embodiments, the top view of the second alignment patterns 205C includes discrete vertical strips and discrete horizontal strips, where the discrete vertical strips are located at the upper-left portions of the dashed box framing the alignment pattern, and the discrete horizontal strips are located at the lower-left portions of the dashed box. The shape of the second alignment patterns 205A, 205B, and 205C are provided for illustrative purposes only and are not meant to limit the scope of the embodiments described herein. Any shape (e.g., circles, ovals, triangles, squares, L-shapes, a combination thereof, or the like) can be used as the second alignment patterns 205. The top-view shape of the second alignment pattern 205 near each corner of the first region R21 (or along each side of the first region R21) may be the same or similar. In other embodiments, the top-view shapes of the second alignment patterns 205 at different locations may be different. The top-view shape/profile of the second alignment patterns 205 and the top-view shape/profile of the first alignment patterns 105 may be different. In some embodiments, the second alignment patterns 205 and the first alignment patterns 105 are formed to identify a proper orientation/location of the first IC component 100A on the second IC component 200. The use of the first/second alignment patterns has various advantages. For example, undesired shifts of the first IC component 100A may be reduced or avoided while bonding the first IC component 100A to the second IC component 200. Moreover, damage to the first IC component 100A caused by misalignment may be reduced or avoided. This will be described in greater detail in accompanying with FIGS. 3A-3E.

FIGS. 3A, 3D, and 3E illustrate schematic cross-sectional views of intermediate steps during a process for forming a semiconductor structure, FIG. 3B illustrates a schematic and simplified top-down plan view of the bonded structure shown in FIG. 3A, FIG. 3C illustrates a schematic and partial perspective view of the bonded structure shown in FIG. 3A, in accordance with some embodiments. Unless specified otherwise, the materials of the components in these embodiments are essentially the same as the like components, which are denoted by like reference numerals in the embodiments shown in FIGS. 1A-1B and FIGS. 2A-2B. Although method embodiments may be discussed as being performed in a particular order, other method embodiments may be performed in any logical order.

Referring to Figured 3A-3C and with reference to FIGS. 1A-1B and 2A-2B, the first IC component 100A may be stacked upon and bonded to the second IC component 200. The first IC component 100A may have a lateral dimension W1 less than a lateral dimension W2 of the second IC component 200. In some embodiments, a plurality of first IC components 100A is bonded to the second IC component 200, where the first IC components 100A are located in different regions on the second IC component 200 and laterally separated from each other. In some embodiments, the first IC component 100A is a semiconductor die, the second IC component 200 is a semiconductor wafer, and the bonding involves the die-to-wafer bonding.

In some embodiments, the first IC component 100A is disposed on the second IC component 200 using a pick-and-place process. For example, a pick-and-place tool (not shown) including a pick-up head, a robotic arm, a controller, a sensor, and/or any other elements is configured to perform the pick-and-place process. In some embodiments, the first IC component 100A (e.g., known-good-die) is picked up and transferred towards an intended position on the second IC component 200 by the pick-and-place tool. The first IC component 100A carried by the pick-and-place tool may be positioned over and aligned with the second IC component 200. The first IC component 100A may then be placed on the second IC component 200. For example, the first IC component 100A is placed onto the second IC component 200 at locations where the first regions R11 and R21 are aligned and overlap each other and the second regions R12 and R22 are aligned and overlap each other. The first bonding features 1042 may overlap and may be substantially aligned with the second bonding features 2042, within process variations.

It is appreciated that the precise alignment may reduce manufacturing defects and allows for subsequently formed redistribution structure designs having smaller buffer areas and finer pitch. In some embodiments, the first and second alignment patterns 105 and 205 are used to align the first IC component 100A on the second IC component 200 during the pick-and-place process and/or the subsequently performed bonding process. For example, the alignment includes aligning the first alignment patterns 105 with the second alignment patterns 205. In some embodiments, the first alignment patterns 105 and/or the second alignment patterns 205 are sensible by one or more sensor of the pick-and-place tool via visible light, infrared or any other suitable electromagnetic radiations with suitable wavelengths. For example, the sensor is configured to monitor the alignment and transmit suitable signals to the controller, and the pick-up head may move accordingly until the first alignment pattern 105 of the first IC component 100A is aligned with the second alignment pattern 205 of the second IC component 200. The precise alignment may avoid shifting of the first IC component 100A, which may cause electrical failures of the resulting semiconductor structure.

With continued reference to FIGS. 3A-3C, after the first IC component 100A is disposed on the second IC component 200, the first and second alignment patterns 105 and 205 may be arranged in a matrix of a staggered manner in the cross-sectional view and the top-down plan view. For example, the segment of the first alignment patterns 105 is located directly above the gap between the discrete segments of the second alignment patterns 205 in the cross-sectional view of FIG. 3A. The segment of the first alignment patterns 105 may be laterally and vertically offset from the discrete segments of the second alignment patterns 205. In some embodiments, an area framing the first alignment patterns 105 and an area framing the second alignment patterns 205 may coincide in the top-down view. For example, the dashed boxes framing the first and second alignment patterns 105 and 205 overlap and coincide as shown in FIG. 3B. The segments of the first alignment patterns 105 may not overlap the segments of the second alignment patterns 205 in the top-down plan view. In some embodiments, when the first alignment patterns 105 are aligned with the second alignment patterns 205, the segments of the first alignment patterns 105 respectively have a shift in the X-direction and Y-direction with respect to the segments of the second alignment patterns 205.

Still referring to FIGS. 3B and 3C, the boundary of the first IC component 100A may be fully disposed within the boundary of the second IC component 200. For example, a top-view of the first and second alignment patterns 105 and 205 may be in various shapes after the alignment and placement. For example, in a scenario, the first alignment pattern 105A is aligned with the second alignment pattern 205A, where the discrete square (or rectangular) segments of the second alignment pattern 205A are located at the corners of the dashed box framing the alignment pattern, and the continuous cross segment of the first alignment pattern 105A is located at the center of the dashed box without overlapping the second alignment pattern 205A, in the top-down view. In another scenario, the first alignment pattern 105B is aligned with the second alignment pattern 205A, where the discrete square (or rectangular) segments of the first and second alignment patterns 105A and 205A are alternately arranged along the sides of the dashed box framing the alignment pattern, and the center segment of discrete cross of the second alignment patterns 205A is located at the center of the dashed box. In still another scenario, the first alignment pattern 105B is aligned with the second alignment pattern 205B, where the center of discrete cross segments of the first alignment pattern 105B is located at the center of the dashed box framing the alignment pattern, and the discrete vertical strips and discrete horizontal strips of the second alignment patterns 205B are arranged at the corners of the dashed box without overlapping the first alignment pattern 105B, in the top-down view. In yet another scenario, the first alignment pattern 105C is aligned with the second alignment pattern 205C, where the discrete vertical strips of the first and second alignment pattern 105C and 205C are arranged in the upper portion of the dashed box framing the alignment pattern, and the discrete horizontal strips of the first and second alignment pattern 105C and 205C are arranged in the lower portion of the dashed box. Other configuration of the aligned first and second alignment patterns 105/205 are possible. The top-view shape of the aligned first and second alignment patterns 105/205 are provided herein for illustrative purposes only and are not meant to limit the scope of the embodiments described herein.

In some embodiments, the first and second alignment patterns 105 and 205 are referred to as overlay marks which are used to measure overlay error or check alignment accuracy. For example, when measuring an overlay error using the first and second alignment patterns 105 and 205, an X-directional deviation is measured in an X direction of the first and second alignment patterns 105 and 205, and a Y-directional deviation is measured in a Y direction of the first and second alignment patterns 105 and 205. By aligning the first alignment patterns 105 with the second alignment patterns 205 in a staggered manner within the overlapped second regions R12/R22, the size of the first IC component 100A may be arbitrarily increased or reduced without being limited to the position of the second alignment patterns 205 of the second IC component 200. For example, if the second alignment patterns 205 are disposed at the position outside the area where the first IC component 100A is predetermined to be disposed on, the die edge of the first IC component 100A may be too close to the second alignment patterns 205 and affect alignment and measurement during the bonding process. Also, in the case where the second alignment patterns 205 are disposed on the region outside the area where the first IC component 100A is predetermined to be bonded, the first IC component 100A cannot be arbitrarily increased, since a larger size of the first IC component 100A will partially or entirely block the second alignment patterns 205 to affect alignment and measurement during the bonding process. By configuring the alignment region (e.g., R22) of the second IC component 200 overlapping the alignment region (e.g., R12) of the first IC component 100A, the alignment and measurement will not be affected due to the change in larger size of the first IC component 100A.

Turning back to FIG. 3A, after placing the first IC component 100A on the second IC component 200, a bonding process may be performed to bond the first IC component 100A to the second IC component 200. In some embodiments, before performing the bonding process, a surface treatment (e.g., plasma treatment) is performed on the bonding surfaces of the first and second bonding structures 104 and 204. After the surface treatment, the bonding surfaces of the first and second bonding structures 104 and 204 may be cleaned by chemical cleaning and/or de-ionized water cleaning. The bonding surfaces of the first and second bonding structures 104 and 204 may then be bonded together. The respective first bonding feature 1042 and the second bonding feature 2042 may be aligned with and pre-bonded to each other. In the illustrated embodiment, each of the bonding pads 1042P is aligned with and bonded to one of the bonding pads 2042P. Alternatively, the bonding involves via-to-pad bonding (e.g., the bonding vias 1042V are bonded to bonding pads 2042P, or the bonding pads 1042P are bonded to the bonding vias 2042V) or via-to-via bonding (e.g., the bonding vias 1042V and 2042V are bonded together), depending on the configuration of the bonding structures. After the pre-bonding, the dielectric materials and the conductive materials of the first bonding structure 104 are bonded to the dielectric material and the conductive material of the second bonding structure 204, respectively. For example, the first bonding structure 104 of the first IC component 100A is physically and electrically connected to the second bonding structure 204 of the second IC component 200. In some embodiments, the first bonding dielectric layer 1041 is bonded to the second bonding dielectric layer 2041, and the first and second bonding features 1042 and 2042 are bonded to each other.

The bonds of the first and second bonding structures 104 and 204 may be strengthened in an annealing process. During the annealing, metals in the first and second bonding features 1042 and 2042 may diffuse to each other to form metal-to-metal bonds. After the bonding process, metal-to-metal (e.g., copper-to-copper) bonds and dielectric-to-dielectric (e.g., oxide-to-oxide) bonds may be formed at the bonding interface 12F of the first and second IC components 100A and 200. The bonding interface 12F may be substantially flat and level, within process variations. The first alignment patterns 105 and the second alignment patterns 205 may be laterally offset from each other, the first and second alignment patterns 105 and 205 may not be directly bonded to each other. For example, the first alignment patterns 105 formed of the conductive materials are bonded to the second bonding dielectric layer 2041, and the second alignment patterns 205 formed of the conductive materials are bonded to the first bonding dielectric layer 1041. The metal-to-dielectric (e.g., copper-to-oxide) bonds and the dielectric-to-dielectric (e.g., oxide-to-oxide) bonds may be formed at the bonding interface 12F within the second regions R12/R22.

Referring to FIG. 3D and with reference to FIG. 3A, an insulating encapsulation 220 may be formed over the second IC component 200 to laterally cover the first IC component 100A. The insulating encapsulation 220 may be or include molding compound, molding underfill, epoxy resin, or the like, and may be applied by compression molding, transfer molding, etc. To form the insulating encapsulation 220, a curing process is optionally performed to harden the insulating material for optimum protection. In alternative embodiments, the insulating encapsulation 220 includes a dielectric material (e.g., an oxide, a nitride, or the like) and may be formed using CVD, PVD, ALD, or the like. In some embodiments, the insulating encapsulation 220 is formed by: forming an insulating material on the second IC component 200 to bury the first IC component 100A, and performing a planarization process (e.g., CMP, grinding, etching, and/or the like) to remove excess portion of the insulating material. During the planarization process, a portion of the first semiconductor substrate 101 may be removed to accessibly expose the TSVs 102. For example, the back side 101b of the first semiconductor substrate 101 is thinned down to reveal the second ends 102b of the TSVs 102 for further electrical connection. The back side 101b of the first semiconductor substrate 101 and the second ends 102b of the TSVs 102 may be collectively viewed as the back surface 100Ab of the first IC component 100A. In some embodiments, the surface 220b of the insulating encapsulation 220 is substantially leveled (or coplanar) with the back surface 100Ab of the first IC component 100A, within process variations.

Referring to FIG. 3E and with reference to FIG. 3D, a redistribution structure 230 may be formed on the insulating encapsulation 220 and the first IC component 100A. The redistribution structure 230 may include a dielectric layer 231 and conductive patterns 232 formed in/on the dielectric layer 231. The redistribution structure 230 is shown as an example; however, more dielectric layers and conductive patterns may be formed in the redistribution structure. The material(s) of the dielectric layer 231 may be or include a photo-sensitive material such as PBO, PI, BCB, a combination thereof, or the like. The dielectric layer 231 may be deposited on the surface 220b of the insulating encapsulation 220 and the back surface 100Ab of the first IC component 100A, and the dielectric layer 231 may reveal at least a portion of the second ends 102b of the TSVs 102. The material(s) of the conductive patterns 232 may be or include copper, nickel, titanium, alloys thereof, a combination thereof, or the like. The conductive patterns 232 may include conductive features such as conductive lines, conductive vias, and/or conductive pads, and these conductive features are collectively referred to as redistribution layers or redistribution lines. The bottommost one of the conductive patterns 232 may be in physical and electrical contact with the second ends 102b of the TSVs 102. In some embodiments, the topmost one of the conductive patterns 232 includes under bump metallization (UBM) pads for the subsequently formed terminals landing thereon.

In some embodiments, a plurality of conductive terminals 240 is formed on the topmost one of the conductive patterns 232. The conductive terminals 240 may include a conductive material such as solder, copper, aluminum, gold, nickel, silver, palladium, tin, the like, and/or a combination thereof. The conductive terminals 240 may be or include solder balls, metal pillars, controlled collapse chip connection (C4) bumps, micro-bumps, electroless nickel-electroless palladium-immersion gold (ENEPIG) bumps, ball grid array (BGA) connectors, and/or the like, and may be formed by ball placement, evaporation, electroplating, printing, solder transfer, or any suitable process. Up to here, a semiconductor structure 10A is provided. In some embodiments, one or more semiconductor process (e.g., singulation, packaging, coupling to another component, and/or the like) is performed on the semiconductor structure 10A to form semiconductor products.

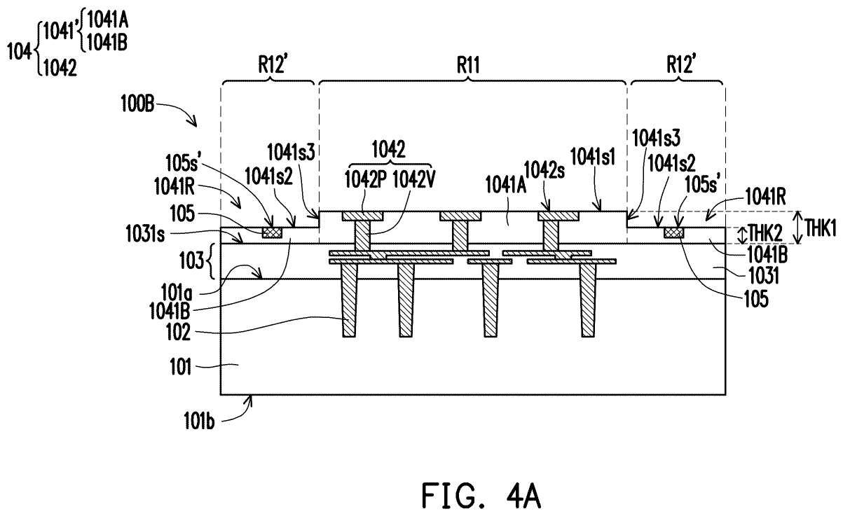

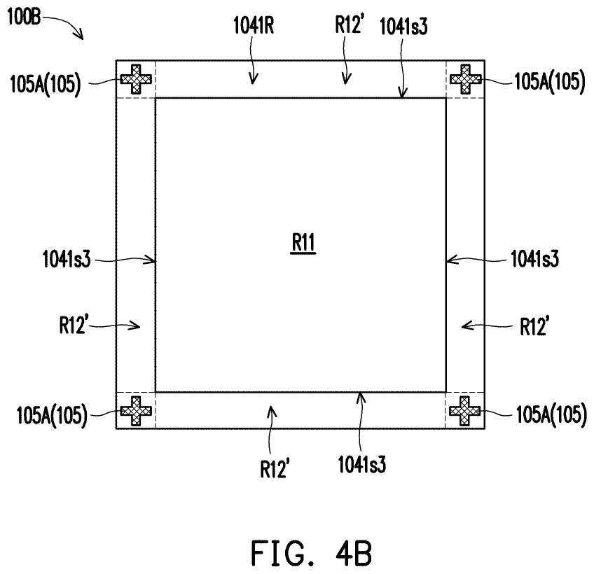

FIG. 4A illustrates a schematic cross-sectional view of a first IC component, and FIG. 4B illustrates a schematic top-down plan view of the first IC component shown in FIG. 4A, in accordance with some embodiments. Unless specified otherwise, the materials of the components in these embodiments are essentially the same as the like components, which are denoted by like reference numerals in the embodiments shown in FIGS. 1A and 1B.

Referring to FIGS. 4A-4B and with reference to FIGS. 1A-1B, a first IC component 100B may be similar to the first IC component 100A described in FIGS. 1A-1B, and thus the detailed descriptions are not repeated for the sake of brevity. The difference between the first IC components 100A and 100B includes that the first bonding dielectric layer 1041′ of the first IC component 100B may include a first portion 1041A in the first region R11 and a second portion 1041B surrounding the first portion 1041A and in the second region R12′. In some embodiments, a thickness THK1 of the first portion 1041A is less than a thickness THK2 of the second portion 1041B. For example, after depositing a bonding dielectric material on the first interconnect structure 103, a recess 1041R may be performed to thin down a portion of the bonding dielectric material in the second region R12′ by using etching or any suitable removal process, thereby forming the first bonding dielectric layer 1041′. The recess 1041R around the periphery of the first IC component 100B may provide stress relief for stress incurred during subsequent bonding/molding processes. The top surface 1041s2 of the second portion 1041B may be between the top surface 1031s of the first dielectric layer 1031 of the first interconnect structure 103 and the top surface 1041s1 of the first portion 1041A. The sidewall 1041s3 of the first bonding dielectric layer 1041′ may be connected to the top surfaces 1041s1 and 1041s2, where the sidewall 1041s3 may be located at the intersection of the first region R11 and the second region R12′.

In some embodiments, the first bonding features 1042 are formed in the first portion 1041A of the first bonding dielectric layer 1041′, and the first alignment patterns 105 are below the recess 1041R and formed in the second portion 1041B of the first bonding dielectric layer 1041′. The first IC component 100B may be accurately placed to its intended position on the second IC component 200 by using the first alignment patterns 105. The surfaces 105s′ of the first alignment patterns 105 may be below the top surfaces 1042s of the first bonding features 1042. The top surfaces 1042s of the first bonding features 1042 may be substantially leveled (or coplanar) with the top surface 1041s1 of the first portion 1041A and may be above the top surface 1041s2 of the second portion 1041B. The first alignment patterns 105 may be disposed at the corners of the first IC component 100B. Alternatively, the first alignment patterns 105 may be disposed anywhere in the second region R12′. The first alignment patterns 105A shown in FIG. 4B is an example, the first alignment patterns may be replaced with other shapes of the alignment marks as described previously.

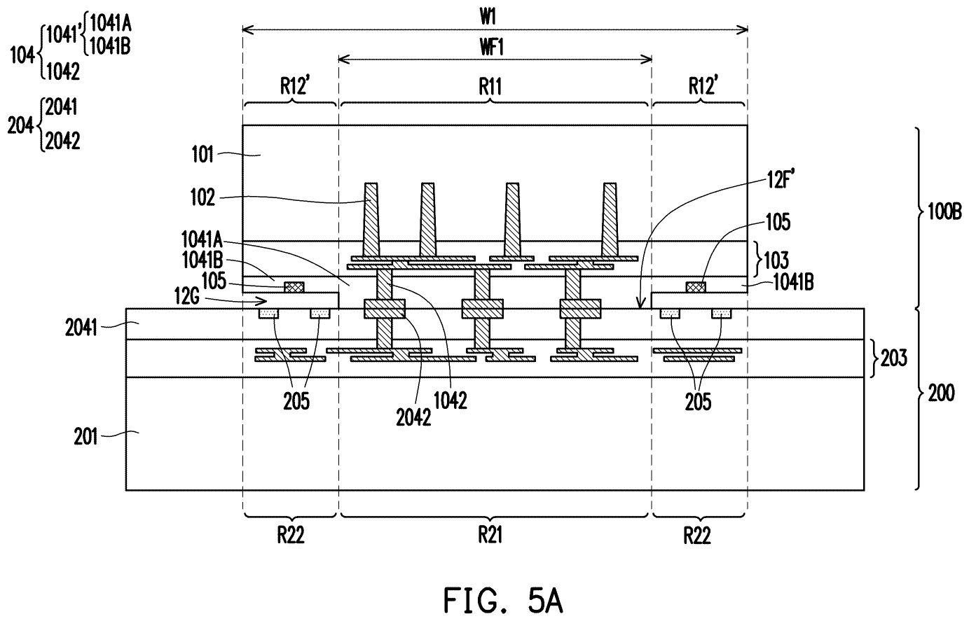

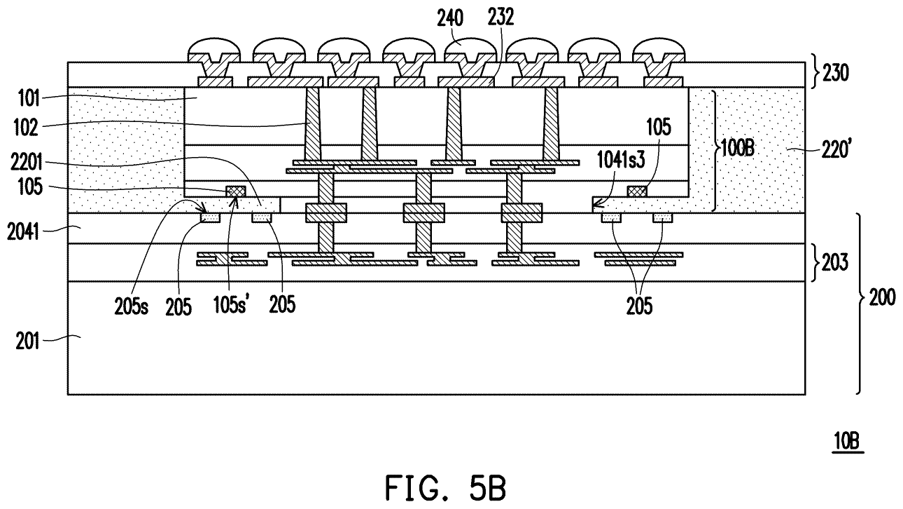

FIGS. 5A and 5B illustrate schematic cross-sectional views of intermediate steps during a process for forming a semiconductor structure, in accordance with some embodiments. Unless specified otherwise, the materials and the formation methods of the components in these embodiments are essentially the same as the like components, which are denoted by like reference numerals in the embodiments shown in FIGS. 3A-3E. The details regarding the materials of the components may thus be found in the discussion of the embodiments shown in FIGS. 3A-3E. Although method embodiments may be discussed as being performed in a particular order, other method embodiments may be performed in any logical order.

Referring to FIG. 5A and with reference to FIGS. 4A-4B and FIGS. 3A-3C, the first IC component 100B may be stacked upon and physically and electrically bonded to the second IC component 200. For example, the first IC component 100B is picked and placed on the second IC component 200 by using the first and second alignment patterns 105 and 205 to ensure the alignment accuracy for the subsequent processes, and then the bonding process is performed to bond the first IC component 100B to the second IC component 200. The processes may be similar to the processes described in FIGS. 3A-3C. The difference includes that a gap 12G is formed between the first IC component 100B and the second IC component 200 after the bonding process, where the gap 12G corresponds to the recess 1041R of the first bonding dielectric layer 1041′ and is located in the overlapped second region R12′/R22. The gap 12G may serve as a stress buffer during the bonding process, and hence effectively reduce the cracking/delamination of interface. The lateral dimension WFI of the bonding interface 12F may be less than the lateral dimension W1 of the first IC component 100B. In some embodiments, the lateral dimension WFI of the bonding interface 12F is the lateral dimension of the first portion 1041A of the first bonding dielectric layer 1041′. The second portion 1041B of the first bonding dielectric layer 1041′ may be vertically spaced apart from the second bonding structure 2041. The first alignment patterns 105 may be offset from second alignment patterns 205 in the X, Y, and Z-directions.

Referring to FIG. 5B and with reference to FIG. 5A and FIGS. 3D-3E, an insulating encapsulation 220′ may be formed on the second IC component 200 to cover the first IC component 100B. The material and the forming process of the insulating encapsulation 220′ may be similar to the material and the forming process of the insulating encapsulation 220 described in FIG. 3D, except that the insulating encapsulation 220′ may have a protruded portion 2201 extending into the gap 12G between the first and second IC component 100B and 200. The gap 12G may serve as a stress buffer when forming the insulating encapsulation 220′ (e.g., during a molding process), and hence effectively reduce the cracking/delamination of interface. The surfaces 105s′ of the first alignment patterns 105, the surfaces 205s of the second alignment patterns 205, and the sidewall 1041s3 of the first bonding dielectric layer 1041′ may be in direct contact with the protruded portion 2201 of the insulating encapsulation 220′.

In some embodiments, after forming the insulating encapsulation 220′, the redistribution structure 230 is formed on the insulating encapsulation 220′ and the first IC component 100B. The conductive terminals 240 may be formed on the redistribution structure 230 to electrically connect the conductive patterns 232. The formation of the redistribution structure 230 and the conductive terminals 240 may be similar to the processes described in FIG. 3E. Up to here, a semiconductor structure 10B is provided. One or more semiconductor process (e.g., singulation, packaging, coupling to another component, and/or the like) may be performed on the semiconductor structure 10B to form semiconductor products.

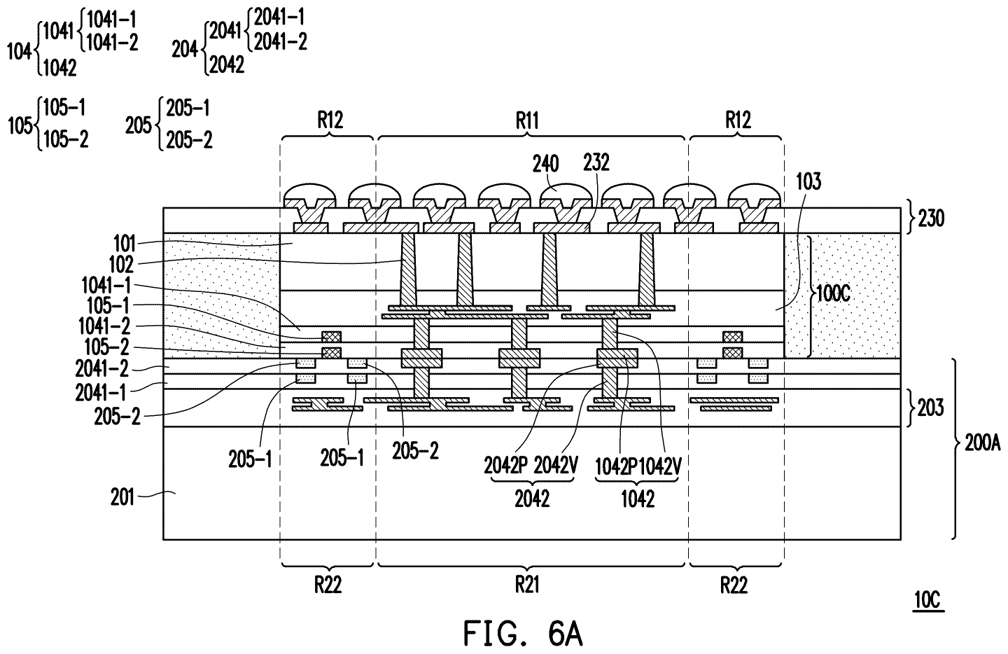

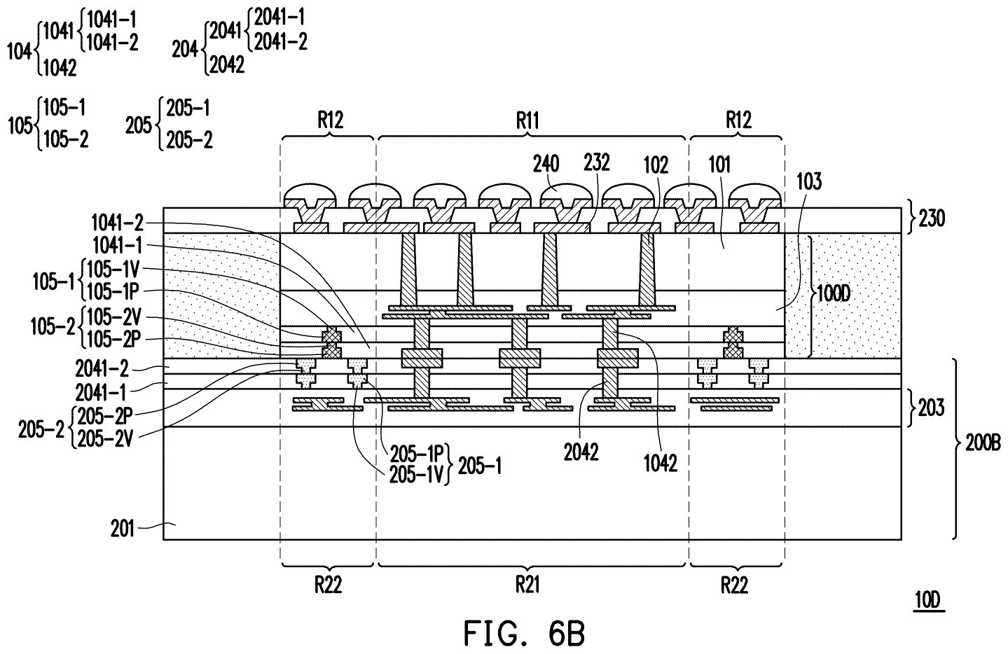

FIGS. 6A and 6B illustrate schematic cross-sectional views of different semiconductor structures, in accordance with some embodiments. Unless specified otherwise, like components are indicated by the like reference numerals.

Referring to FIG. 6A and FIG. 3E, a semiconductor structure 10C shown in FIG. 6A may be similar to the semiconductor structure 10A shown in FIG. 3E, except for the bonding structures and the alignment patterns. For example, the first bonding dielectric layer 1041 of the first bonding structure 104 of the first IC component 100C includes a first sublayer 1041-1 connected to the first interconnect structure 103 and a second sublayer 1041-2 connected to the first sublayer 1041-1 and bonded to the second bonding dielectric layer 2041. In some embodiments, the bonding pads 1042P of the first bonding features 1042 are formed in the second sublayer 1041-2, and the bonding vias 1042V of the first bonding features 1042 connected to the bonding pads 1042P penetrate through the first and second sublayers 1041-1 and 1041-2 to be connected to the first interconnect structure 103. The first alignment patterns 105 may be formed in both of the first and second sublayers 1041-1 and 1041-2 within the second region R12. For example, the first-level pattern 105-1 of the first alignment patterns 105 is formed in the first sublayer 1041-1, and the second-level pattern 105-2 of the first alignment patterns 105 is formed in the second sublayer 1041-2 and vertically aligned with the first-level pattern 105-1 of the first alignment patterns 105. The first-level pattern 105-1 and the second-level pattern 105-2 of the first alignment patterns 105 may overlap in the top-down view (not shown).

In some embodiments, the second bonding dielectric layer 2041 of the second bonding structure 204 of the of the second IC component 200A includes a first sublayer 2041-1 connected to the second interconnect structure 203 and a second sublayer 2041-2 connected to the first sublayer 2041-1 and bonded to the second sublayer 1041-2 of the first bonding dielectric layer 1041. In some embodiments, the bonding pads 2042P of the second bonding features 2042 are formed in the second sublayer 2041-2 and bonded to the bonding pads 1042P, and the bonding vias 2042V of the second bonding features 2042 connected to the bonding pads 2042P penetrate through the first and second sublayers 2041-1 and 2041-2 to be connected to the second interconnect structure 203. The second alignment patterns 205 may be formed in both of the first and second sublayers 2041-1 and 2041-2 within the second region R22. For example, the first-level pattern 205-1 of the second alignment patterns 205 is formed in the first sublayer 2041-1, and the second-level pattern 205-2 of the second alignment patterns 205 is formed in the second sublayer 2041-2 and vertically aligned with the first-level pattern 205-1 of the second alignment patterns 205. The first-level pattern 205-1 and the second-level pattern 205-2 of the second alignment patterns 205 may overlap in the top-down view (not shown).

In some embodiments, during the pick-and-place process, the position of the first IC component 100C on the second IC component 200A is determined through the first and second alignment patterns 105 and 205, and hence the first IC component 100C is placed accurately to the intended position on the second IC component 200A. In some embodiments, after bonding the first IC component 100C to the second IC component 200A, the first and second-level pattern 105-1 and 105-2 of the first alignment patterns 105 are aligned with the first and second-level pattern 205-1 and 205-2 of the second alignment patterns 205 in a matrix of a staggered manner in the cross-sectional view and the top-down plan view, where the top-down plan view can be referred to the description associated with FIG. 3B.

Referring to FIG. 6B and FIG. 6A, a semiconductor structure 10D shown in FIG. 6B may be similar to the semiconductor structure 10C shown in FIG. 6A, except for the alignment patterns. For example, the first-level pattern 105-1 of the first alignment pattern 105 formed in the first sublayer 1041-1 of the first bonding dielectric layer 1041 of the first IC component 100D includes a pad portion 105-1P and a via portion 105-1V connected to the pad portion 105-1P and landing on the first interconnect structure 103. Similarly, the second-level pattern 105-2 of the first alignment pattern 105 formed in the second sublayer 1041-2 of the first bonding dielectric layer 1041 includes a pad portion 105-2P and a via portion 105-2V connected to the pad portion 105-2P and landing on the pad portion 105-1P. The pad and via portions (105-1P and 105-1V or 105-2P and 105-2V) may collectively have an inverted T-shape cross-section.

In some embodiments, the first-level pattern 205-1 of the second alignment pattern 205 formed in the first sublayer 2041-1 of the second bonding dielectric layer 2041 of the second IC component 200B includes a pad portion 205-1P and a via portion 205-1V connected to the pad portion 205-1P and landing on the second interconnect structure 203. Similarly, the second-level pattern 205-2 of the second alignment pattern 205 formed in the second sublayer 1041-2 of the second bonding dielectric layer 2041 of the second IC component 200B includes a pad portion 205-2P and a via portion 205-2V connected to the pad portion 205-2P and landing on the pad portion 205-1P. The pad and via portions (205-1P and 205-1V or 205-2P and 205-2V) may collectively have an inverted T-shape cross-section. During the pick-and-place process, the position of the first IC component 100D on the second IC component 200B may be determined through the first and second alignment patterns 105 and 205, and hence the first IC component 100D is placed accurately to the intended position on the second IC component 200B. After bonding the first IC component 100D to the second IC component 200B, the first and second-level pattern 105-1 and 105-2 of the first alignment patterns 105 are aligned with the first and second-level pattern 205-1 and 205-2 of the second alignment patterns 205 in a matrix of a staggered manner in the cross-sectional view and the top-down plan view.

The first and second alignment patterns 105 and 205 may be used for checking alignment accuracy between the first and second IC components. By using the first and second alignment patterns 105 and 205, undesired shift and rotation of the first IC component may be reduced or avoided. Moreover, damage of the first IC component due to misalignment may be reduced or avoided. It is appreciated that as the design rule shrinks and the fabrication of the integrated circuits tends to use multi-layer design, the area cost issue of the alignment marks becomes seriously high. By configuring the alignment region (e.g., R22) of the second IC component overlapping the alignment region (e.g., R12) of the first IC component and within the boundary of the first IC component, the alignment and measurement will not be affected due to the change in larger size of the first IC component, and the area cost of the alignment patterns may be reduced.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor structure includes a first IC component and a second IC component underlying and electrically coupled to the first IC component. The first IC component includes a first bonding structure comprising a first bonding dielectric layer and a first bonding feature disposed in the first bonding dielectric layer, and a first alignment pattern disposed in the first bonding dielectric layer. The second IC component includes a second bonding structure including a second bonding dielectric layer bonded to the first bonding dielectric layer and a second bonding feature disposed in the second bonding dielectric layer and bonded to the first bonding feature, and a second alignment pattern disposed in the second bonding dielectric layer and aligned with the first alignment pattern in a staggered manner. The second alignment pattern is disposed within a boundary of the first IC component in a top-down view.

According to some alternative embodiments, a semiconductor structure includes a first IC component and a second IC component underlying and electrically coupled to the first IC component. A size of the second IC component is larger than that of the first IC component. The first IC component includes a first functional region, a first alignment region outside the first functional region, and a first alignment pattern disposed within the first alignment region. The second IC component includes a second functional region electrically coupled to the first functional region, a second alignment region outside the second functional region and overlapping the first alignment region in a stacking direction of the first and second IC components, and a second alignment pattern disposed within the second alignment region and aligned with the first alignment pattern in a staggered manner in the stacking direction. The first and second alignment patterns are electrically floating.

According to some alternative embodiments, a manufacturing method of a semiconductor structure includes providing a first IC component, providing a second IC component, and bonding the first IC component to the second IC component. The first IC component includes a first bonding structure including a first bonding dielectric layer and a first bonding feature disposed in the first bonding dielectric layer, and a first alignment pattern disposed in the first bonding dielectric layer. The second IC component includes a second bonding structure including a second bonding dielectric layer bonded to the first bonding dielectric layer and a second bonding feature disposed in the second bonding dielectric layer and bonded to the first bonding feature, and a second alignment pattern disposed in the second bonding dielectric layer. The first IC component is bonded to the second IC component by using the first and second alignment patterns. After bonding the first IC component to the second IC component, the second alignment pattern is aligned with the first alignment pattern in a staggered manner, and the second alignment pattern is disposed within a boundary of the first IC component in a top-down view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first integrated circuit (IC) component comprising:
a first bonding structure comprising a first bonding dielectric layer and a first bonding feature disposed in the first bonding dielectric layer; and
a first alignment pattern disposed in the first bonding dielectric layer; and
a second IC component underlying and electrically coupled to the first IC component, the second IC component comprising:
a second bonding structure comprising a second bonding dielectric layer bonded to the first bonding dielectric layer and a second bonding feature disposed in the second bonding dielectric layer and bonded to the first bonding feature; and
a second alignment pattern disposed in the second bonding dielectric layer and aligned with the first alignment pattern in a staggered manner, wherein the second alignment pattern is disposed within a boundary of the first IC component in a top-down view.

2. The semiconductor structure of claim 1, wherein bonding surfaces of the first bonding dielectric layer and the first bonding feature are substantially leveled with a bonding surface of the first alignment pattern which is bonded to the second bonding dielectric layer.

3. The semiconductor structure of claim 1, wherein bonding surfaces of the second bonding dielectric layer and the second bonding feature are substantially leveled with a bonding surface of the second alignment pattern which is bonded to the first bonding dielectric layer.

4. The semiconductor structure of claim 1, further comprising:
an insulating encapsulant disposed on the second IC component and laterally covering the first IC component.

5. The semiconductor structure of claim 1, wherein the first IC component further comprises a semiconductor substrate disposed over the first bonding structure and a through substrate via penetrating through the semiconductor substrate and electrically coupled to the first bonding feature.

6. The semiconductor structure of claim 1, wherein the first bonding dielectric layer comprises a first portion in which the first bonding feature is disposed and a second portion in which the first alignment pattern is disposed, wherein a thickness of the second portion is less than a thickness of the first portion.

7. The semiconductor structure of claim 6, further comprising:
an insulating encapsulant disposed on the second IC component and covering the first IC component, the insulating encapsulant comprising a protruded portion extending into a gap between the second bonding dielectric layer and the second portion of the first bonding dielectric layer.

8. The semiconductor structure of claim 7, wherein the insulating encapsulant is in physical contact with the first and second alignment patterns.

9. The semiconductor structure of claim 1, wherein:
the first bonding dielectric layer comprises a first sublayer and a second sublayer connected to the first sublayer and the second bonding dielectric layer, and
the first alignment pattern comprises a first-level pattern in the first sublayer and a second-level pattern in the second sublayer and vertically aligned with the first-level pattern.

10. The semiconductor structure of claim 9, wherein the first-level pattern and the second-level pattern of the first alignment pattern are vertically separated from each other by the second sublayer of the first bonding dielectric layer.

11. The semiconductor structure of claim 9, wherein each of the first-level pattern and the second-level pattern of the first alignment pattern comprises a pad portion and a via portion, and the via portion of the second-level pattern is connected to the pad portion of the second-level pattern and the pad portion of the first-level pattern.

12. A semiconductor structure, comprising:
a first IC component comprising a first functional region, a first alignment region outside the first functional region, and a first alignment pattern disposed within the first alignment region; and
a second IC component underlying and electrically coupled to the first IC component, a size of the second IC component being larger than that of the first IC component, and the second IC component comprising:
a second functional region electrically coupled to the first functional region;
a second alignment region outside the second functional region and overlapping the first alignment region in a stacking direction of the first and second IC components; and
a second alignment pattern disposed within the second alignment region and aligned with the first alignment pattern in a staggered manner in the stacking direction, wherein the first and second alignment patterns are electrically floating.

13. The semiconductor structure of claim 12, wherein the first IC component further comprises:
a first bonding dielectric layer disposed across the first functional region and the first alignment region, wherein the first alignment pattern is disposed in the first bonding dielectric layer; and
a first bonding feature disposed in the first bonding dielectric layer within the first functional region, the first bonding feature being electrically coupled to the second IC component.

14. The semiconductor structure of claim 13, wherein bonding surfaces of the first bonding dielectric layer and the first bonding feature are substantially leveled with a bonding surface of the first alignment pattern.

15. The semiconductor structure of claim 12, wherein a bonding interface of the first IC component and the second IC component is substantially flat and free of solder material.

16. The semiconductor structure of claim 12, further comprising:
an insulating encapsulant disposed on the second IC component and covering the first IC component, the insulating encapsulant comprising a protruded portion vertically interposed between the first alignment region and the second alignment region.

17. A manufacturing method of a semiconductor structure, comprising:
providing a first IC component, wherein the first IC component comprises:
a first bonding structure comprising a first bonding dielectric layer and a first bonding feature disposed in the first bonding dielectric layer; and
a first alignment pattern disposed in the first bonding dielectric layer; and providing a second IC component, wherein the second IC component comprises:
a second bonding structure comprising a second bonding dielectric layer bonded to the first bonding dielectric layer and a second bonding feature disposed in the second bonding dielectric layer and bonded to the first bonding feature; and
a second alignment pattern disposed in the second bonding dielectric layer; and
bonding the first IC component to the second IC component by using the first and second alignment patterns, wherein after bonding the first IC component to the second IC component, the second alignment pattern is aligned with the first alignment pattern in a staggered manner, and the second alignment pattern is disposed within a boundary of the first IC component in a top-down view.

18. The manufacturing method of claim 17, wherein bonding the first IC component to the second IC component comprises:
aligning the first alignment pattern of the first IC component with the second alignment pattern of the second IC component;
bring the first bonding feature of the first IC component in contact with the second bonding feature of the second IC component; and
annealing the first and second bonding features to form metal-to-metal bonds at a bonding interface of the first and second IC components.

19. The manufacturing method of claim 17, further comprising:
forming an insulating encapsulation of the second IC component to laterally cover the first IC component after bonding the first IC component to the second IC component.

20. The manufacturing method of claim 17, wherein providing the first IC component comprises:
recessing a region of a bonding dielectric material to form the first bonding dielectric layer comprising a first portion and a second region thinner than the first portion;
forming the first bonding feature in the first portion of the first bonding dielectric layer; and
forming the first alignment pattern in the second portion of the first bonding dielectric layer.
